(19) United States
(12) Patent Application Publication
(10) Pub. No.: US 2015/0085210 A1
(43) Pub. Date: Mar. 26, 2015

(54) In-Cell Touch Liquid Crystal Display Module and Manufacturing Method For The Same

(71) Applicant: AU OPTRONICS CORPORATION, Hsin-Chu (TW)

(72) Inventor: Min-chien Kuo, Hsin-Chu (TW)

(21) Appl. No.: 14/557,089

(22) Filed: Dec. 1, 2014

Related U.S. Application Data
(63) Continuation of application No. 12/580,423, filed on Oct. 16, 2009.

(30) Foreign Application Priority Data
May 22, 2009 (TW) 098117212

(51) Int. Cl. H05K 1/18; H05K 3/10; H05K 3/00; G02F 1/1333; G02F 1/1335

(52) U.S. Cl. CPC H05K 1/189; G02F 1/13338; G02F 1/133514; G02F 1/133305; H05K 3/0058; H05K 3/10; H05K 2201/10136; G02F 2001/133302
USPC 349/12; 156/60; 156/64

(57) ABSTRACT

An in-cell touch liquid crystal display module includes a first glass substrate, a metal film disposed on the first glass substrate, a liquid crystal layer disposed on the metal film, a second glass substrate disposed on the liquid crystal layer, a conductive layer disposed on the second glass substrate for generating a sensing signal in response to a touch of the conductive layer, a flexible circuit board comprising a plurality of wires coupling the conductive layer, for transmitting the sensing signal, a conductive adhesive for adhering and fastening the flexible circuit board on the second glass substrate, and an insulating adhesive disposed on an periphery of the first glass substrate, for adhering the flexible circuit board on the first glass substrate.

### CLAIM OF PRIORITY

This application is a continuation of U.S. patent application Ser. No. 12/580,423 filed on Oct. 16, 2009, which claims priority to Taiwanese Patent Application No. 098117212 filed on May 22, 2009.

### BACKGROUND OF THE INVENTION

1. Field of the Invention

The present invention relates to a touch panel liquid crystal display (touch panel LCD), and more particularly, to a touch panel liquid crystal display with an in-cell touch liquid crystal display module.

2. Description of Prior Art

With a rapid development of monitor types, novel and colorful monitors with high resolution, e.g., liquid crystal displays (LCDs), are indispensable components used in various electronic products such as monitors for notebook computers, personal digital assistants (PDAs), digital cameras, and projectors. The demand for the novelty and colorful monitors has increased tremendously.

In order to facilitate the carrying and utilization of current LCDs, touch LCD panels that users can touch directly have become a new trend in market development. LCD touch panels which are applied to PDAs are usually combined with LCDs and touch panels to omit keyboard or functional buttons. LCD touch panels usually generate electric signals in response to a touch thereon to control image display of LCDs and implement function control.

Traditional LCD modules employ tapes to paste a LCD panel and a touch panel together as a whole. One end of a flexible printed circuit board (FPC) is connected to a touch panel. But, because the press-fit area between the FPC and the touch panel is quite small, the FPC is inclined to be delaminated from the press-fit area of the touch panel or to be fractured due to minor external forces through the process of assembling. Besides, sometimes, driver integrated circuits (ICs) and other passive elements are disposed on an FPC, and their weight is usually much heavier than that of a single FPC. If an FPC is supported only by the limited press-fit area between an FPC and a touch panel, it is inclined to get loose, resulting in failing to pass strict drop and vibration tests. If an FPC cannot be effectively fastened, defective yield will thus be extremely high, and further, material losses such as FPCs and touch panel driver ICs will be produced.

### BRIEF SUMMARY OF THE INVENTION

It is therefore an object of the present invention to provide an in-cell touch liquid crystal display module which intensifies fixation between an FPC and a touch panel to overcome shortcomings occurring in prior art that a touch panel and an FPC cannot be fastened or easily assembled together.

According to one aspect the present invention, an in-cell touch liquid crystal display module comprises a first glass substrate, a metal film disposed on the first glass substrate, a liquid crystal layer disposed on the metal film, a second glass substrate disposed on the liquid crystal layer, a conductive layer disposed on the second glass substrate for generating a sensing signal in response to a touch of the conductive layer, a flexible circuit board comprising a plurality of wires coupling the conductive layer, for transmitting the sensing signal, and an insulating adhesive disposed on an periphery of the first glass substrate, for adhering the flexible circuit board on the first glass substrate.

According to another aspect the present invention, an in-cell touch liquid crystal display module comprises a first glass substrate, a metal film disposed on the first glass substrate, a liquid crystal layer disposed on the metal film, a second glass substrate disposed on the liquid crystal layer, a conductive layer disposed on the second glass substrate, for generating a sensing signal in response to a touch of the conductive layer, a flexible circuit board comprising a plurality of wires coupling the conductive layer, for transmitting the sensing signal, an conductive adhesive for adhering the flexible circuit board on the second glass substrate to couple the plurality of wires with the flexible circuit board.

According to still another aspect of the present invention, a method of manufacturing an in-cell touch liquid crystal display module comprises the following steps: [0012] (a) providing a first glass substrate; [0013] (b) forming a metal film on the first glass substrate; [0014] (c) providing a second glass substrate; [0015] (d) forming a conductive layer on a top of the second glass substrate and a color filter layer on a bottom of the second glass substrate; [0016] (e) forming a liquid crystal layer between the first glass substrate and the second glass substrate; [0017] (f) aligning and jointing the first glass substrate and the second glass substrate; [0018] (g) providing an insulating adhesive on a periphery of the first glass substrate; [0019] (h) providing a conductive adhesive on the conductive layer; and [0020] (i) adhering a first polarizer and a second polarizer on a top surface of the conductive layer and a bottom surface of the first glass substrate; [0021] (j) providing and pressing a flexible circuit board, so that the flexible circuit board is adhered and fastened to the first glass substrate and the conductive layer by employing the insulating adhesive and the conductive adhesive, respectively.

According to still another aspect of the present invention, an in-cell touch liquid crystal display module comprises a array substrate, a color filter correspondingly disposed on the array substrate, a liquid crystal layer disposed between the array substrate and the color filter, a conductive layer disposed on the color filter, and the color filter sandwiched between the liquid crystal layer and the conductive layer, a flexible circuit board, an anisotropic conductive film disposed on a periphery of the conductive layer, for adhering and fastening the flexible circuit board on the conductive layer.

These and other objectives of the present invention will become apparent to those of ordinary skill in the art after reading the following detailed description of the preferred embodiment that is illustrated in the various figures and drawings.

### BRIEF DESCRIPTION OF THE SEVERAL VIEWS OF THE DRAWINGS

FIG. 1 demonstrates a side view of an in-cell touch liquid crystal display module of a touch liquid crystal display device according to one embodiment of the present invention;

FIG. 2 shows a top view of the in-cell touch liquid crystal display module in FIG. 1;

FIGS. 3A and 3B illustrate a flexible printed circuit board, an insulating adhesive, and a array substrate of the in-cell touch liquid crystal display module in FIG. 2 from two different angles;

FIG. 4 is a flow chart of the in-cell touch liquid crystal display module of the present invention.

### DETAILED DESCRIPTION OF THE INVENTION

Referring to the attached figures, the following embodiments are illustrated to exemplify certain embodiments that the present invention can be applied to. The directional terms adopted in the present invention, such as upper, lower, front, back, left, right, top, and bottom, are defined merely according to the attached figures. Hence, the usage of the directional terms is to assist in elaborating, instead of confining, the present invention for better understanding.

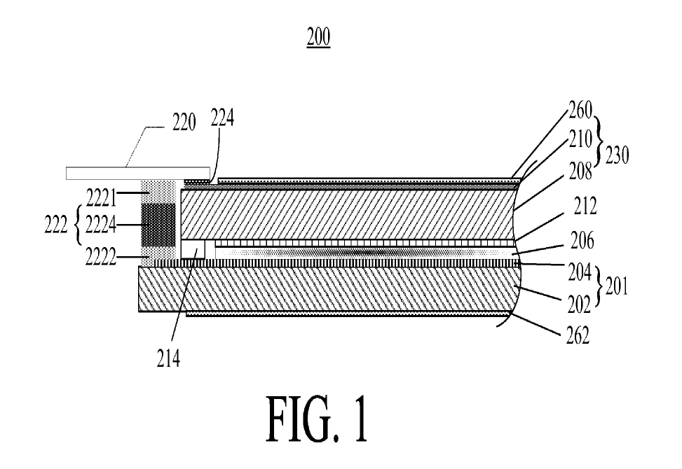

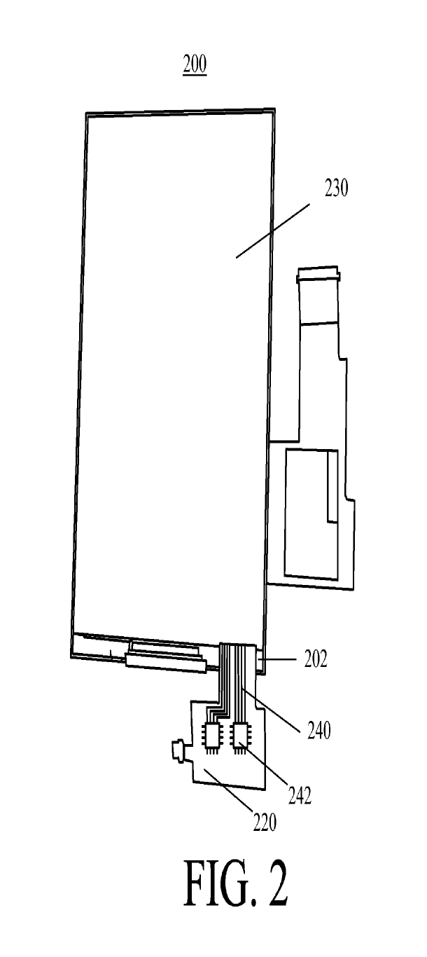

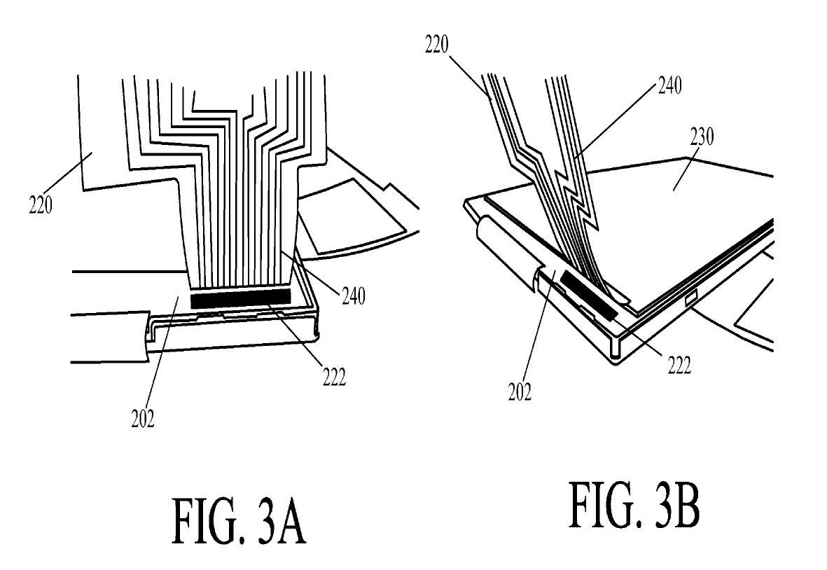

Referring to FIG. 1 as well as FIGS. 2, 3A, and 3B, FIG. 1 demonstrates a side view of an in-cell touch liquid crystal display module 200 of a touch liquid crystal display device according to one embodiment of the present invention; FIG. 2 shows a top view of the in-cell touch liquid crystal display module 200 in FIG. 1; FIGS. 3A and 3B illustrate a flexible printed circuit board (FPC) 220 and an insulating adhesive 222 of the in-cell touch liquid crystal display module 200 in FIG. 2 from two different angles. The in-cell touch liquid crystal display module 200 comprises an array substrate 201, a liquid crystal layer 206, a second glass substrate 208, a conductive layer 210, a color filter 212, an FPC 220, a first polarizer 260, a second polarizer 262, and an insulating adhesive 222. The array substrate 201 comprises a first glass substrate 202 and a metal film 204 on a top surface of the first glass substrate 202. Furthermore, a second polarizer 262 is formed on a bottom surface of the first glass substrate 202. The first glass substrate 202 and the metal film 204 can be regarded as an array substrate 201 which is installed with a plurality of matrix-arranged pixel elements. The liquid crystal layer 206 is disposed between the array substrate 201 and the color filter 212. Corresponding to the array substrate 201, the color filter 212 causes the light that penetrates into the liquid crystal layer 206 to show three different colors—red (R), green (G), and blue (B). The first polarizer 260, the second glass substrate 208 and the conductive layer 210 form an in-cell touch panel 230. The in-cell touch panel 230 connects to the first glass substrate 202 by using sealant 214. The FPC 220 comprises a detecting circuit 242 and a plurality of wires 240 coupled to the conductive layer 210. When a certain position of the conductive layer 210 of the in-cell touch panel 230 is pressed by an external force, a sensing signal is generated by the conductive layers 210 according to the position of point of application of force. After the sensing signal is transmitted to the detecting circuit 242 through the wires 240, the detecting circuit 242 can resolve the coordinate of the point of application of force corresponding to the in-cell touch panel 230. A conductive adhesive 224 (e.g., anisotropic conductive film, ACF) is disposed on a periphery of the conductive layer 210 to adhere and fasten the FPC 220 to the top of the conductive layers 210 and then to facilitate electric signals (e.g. sensing signals) with electrical properties generated by the conductive layer 210 being transmitted to the wires 240.

Moreover, in order to make certain that the FPC 220 and the array substrate 201 are well fastened, the insulating adhesive 222 is disposed on the periphery of the first glass substrate 202 to adhere and fasten the FPC 220 to the first glass substrate 202. Preferably, the insulating adhesive 222 can be transparent double-sided tape when aesthetics and costs are taken into consideration. Double-sided tape comprises a first adhesion layer 2221, a second adhesion layer 2222, and a base layer 2224 disposed therebetween. In one embodiment of the present invention, both of the first adhesion layer 2221 and second adhesion layer 2222 may be made from tackified acrylic; the base layer 2224 may be composed of polyethylene terephthalate (PET). Generally speaking, the total thickness of the metal film 204, the liquid crystal layer 206, the color filter 212, the second glass substrate 208, the conductive layer 210, and the conductive adhesive 224 is roughly between 15 .mu.m and 30 .mu.m. In this embodiment, the total thickness of the metal film 204 (4.5 .mu.m), the liquid crystal layer 206 (3.5 .mu.m), the color filter 212 (1 .mu.m), the second glass substrate 208 (500 .mu.m), the conductive layer 210 (3.625 .mu.m), and the conductive adhesive 224 (18 .mu.m) is about 530.625 .mu.m. In order to protect the FPC 220 from bending after being fastened to the array substrate 201, the thickness of the insulating adhesive 222 should lie between 40 .mu.m and 550 .mu.m. For example, the thickness of Tesa 4972 is about 48 .mu.m. In a preferred embodiment, the thickness of the insulating adhesive 222 is equal to the total thickness of the metal film 204, the liquid crystal layer 206, the color filter 212, the second glass substrate 208, the conductive layer 210, and the conductive adhesive 224. But practically, the present invention also allows the thickness of the insulating adhesive 222 to extend slightly above 550 .mu.m or below 40 .mu.m. In addition, even if the periphery of the metal film 204 partially overlaps with the insulating adhesive 222, the effect of the present invention remains intact.

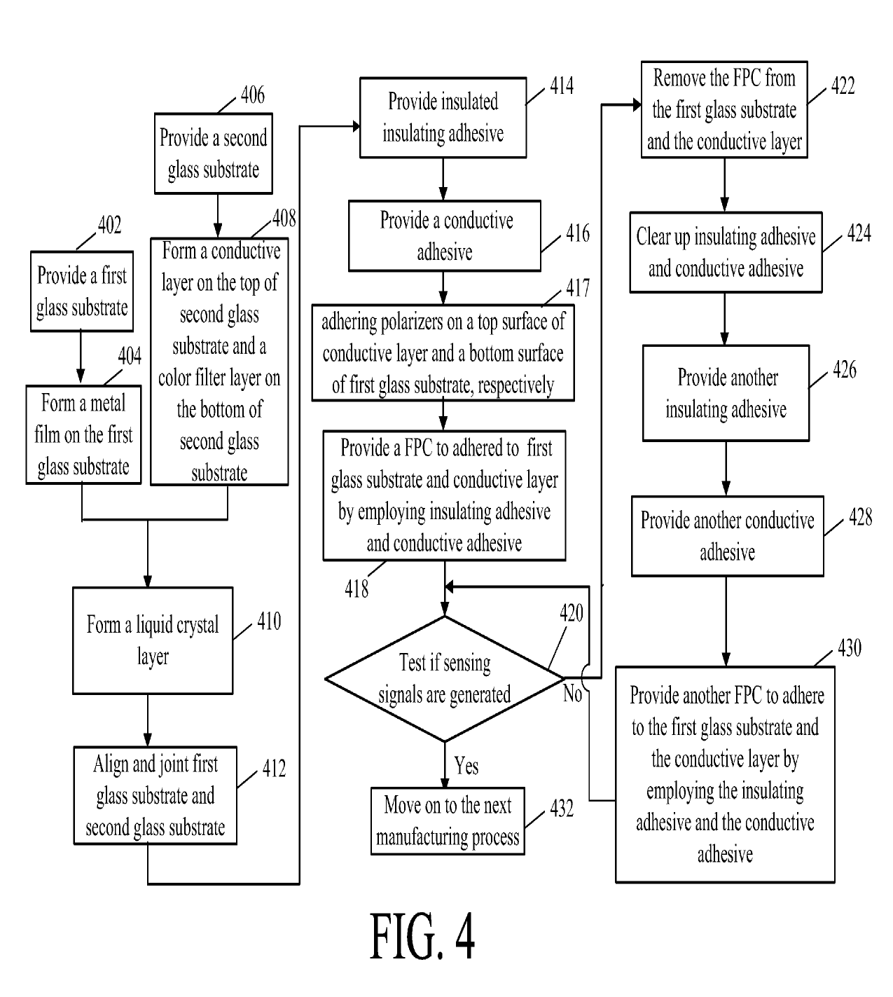

Referring to FIG. 1 and FIG. 4, FIG. 4 is a flow chart of the in-cell touch liquid crystal display module of the present invention. The method of the present invention comprises the following steps: [0032] Step 402: Provide a first glass substrate 202. [0033] Step 404: Form a metal film 204 on the first glass substrate 202. [0034] Step 406: Provide a second glass substrate 208. [0035] Step 408: Form a conductive layer 210 on a top of the second glass substrate 208 and a color filter layer 212 on a bottom of the second glass substrate. [0036] Step 410: Form a liquid crystal layer 206 between the first glass substrate 202 and the second glass substrate 208. [0037] Step 412: Align and joint the first glass substrate 202 and the second glass substrate 208. [0038] Step 414: Provide the periphery of the first glass substrate 202 with an insulating adhesive 222. [0039] Step 416: Provide the conductive adhesive 224. [0040] Step 417: Adhere a first polarizer 260 and a second polarizer 262 on a top surface of the conductive layer 210 and a bottom surface of the first glass substrate 202, respectively. [0041] Step 418: Provide and press an FPC 220, so that the FPC 220 is adhered and fastened to the first glass substrate 202 and the conductive layer 210 by employing the insulating adhesive 222 and the conductive adhesive 224, respectively. [0042] Step 420: Test if sensing signals are generated by the conductive layer 210 and transmitted to the FPC 220. If so, perform Step 432; if not, perform Step 422. [0043] Step 422: Remove the FPC 220 from the first glass substrate 202 and the conductive layer 210. [0044] Step 424: Clear up the insulating adhesive 222 and the conductive adhesive 224. [0045] Step 426: Provide the periphery of the first glass substrate 202 with another insulating adhesive 222. [0046] Step 428: Provide another conductive adhesive 224. [0047] Step 430: Provide and press another FPC 220, so that the FPC is adhered and fastened to the first glass substrate 202 and the conductive layer 210 by employing the insulating adhesive 222 and the conductive adhesive 224, respectively. [0048] Step 432: Move on to the next manufacturing process.

In contrast to prior art, an FPC of an in-cell touch liquid crystal display module in the present invention is adhered and fastened to a first glass substrate (or an array substrate) and a conductive layer (i.e., a touch panel) by employing an insulating adhesive and a conductive adhesive, respectively. Therefore, the FPC can be adhered to the matrix substrate better and less inclined to fall off, especially, through the process of assembling a whole liquid crystal display module. In this way, the defective fraction during manufacture of in-cell touch liquid crystal display modules can be decreased.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

1. An in-cell touch liquid crystal display module, comprising:
a first glass substrate;
a metal film disposed on the first glass substrate;
a liquid crystal layer disposed on the metal film;
a second glass substrate disposed on the liquid crystal layer;
a conductive layer disposed on the second glass substrate, for generating a sensing signal in response to a touch of the conductive layer;
a flexible circuit board, comprising a plurality of wires coupling to the conductive layer, for electrically conducting the sensing signal; and
an electrically insulating adhesive structure, disposed on a periphery of the first glass substrate where the second glass substrate does not overlap, for adhering the flexible circuit board on the first glass substrate and electrically insulating said flexible circuit board from said metal film.

2. The in-cell touch liquid crystal display module of claim 1, wherein said first adhesion point comprises a conductive adhesive for adhering and fastening the flexible circuit board on a periphery of the second glass substrate.

3. The in-cell touch liquid crystal display module of claim 2, wherein the conductive adhesive is an anisotropic conductive film.

4. The in-cell touch liquid crystal display module of claim 1 further comprising a color filter disposed between the liquid crystal layer and the second glass substrate, for filtering out light beam penetrating through the liquid crystal layer.

5. The in-cell touch liquid crystal display module of claim 4 wherein a sum of a thickness of the metal film, the liquid crystal layer, the color filter, the second glass substrate, the conductive layer, and the conductive adhesive is similar to that of the insulating adhesive structure.

6. The in-cell touch liquid crystal display module of claim 1, wherein the insulating adhesive structure is a double-sided tape comprising a first adhesion layer, a second adhesion layer, and a base layer between the first adhesion layer and the second adhesion layer.

7. The in-cell touch liquid crystal display module of claim 1, wherein said electrically insulating adhesive structure partially overlaps said metal film.

8. The in-cell touch liquid crystal display module of claim 1, wherein said flexible circuit board further comprises a first side that comprises said plurality of wires, and said electrically insulating adhesive structure adheres said first side to said first glass substrate.

9. A method of manufacturing an in-cell touch liquid crystal display module, comprising:
(a) providing a first glass substrate;
(b) forming a metal film on the first glass substrate;
(c) providing a second glass substrate;
(d) forming a conductive layer on a top of the second glass substrate and a color filter layer on a bottom of the second glass substrate;
(e) forming a liquid crystal layer between the first glass substrate and the second glass substrate;
(f) aligning and joining the first glass substrate and the second glass substrate;
(g) providing an insulating adhesive on a periphery of the first glass substrate where the second glass substrate does not overlap;
(h) providing a conductive adhesive on the conductive layer;
(i) adhering a first polarizer and a second polarizer on a top surface of the conductive layer and a bottom surface of the first glass substrate; and
(j) providing and pressing a flexible circuit board, so that the flexible circuit board is non-conductively adhered to the first glass substrate by the insulating adhesive and conductively adhered and fastened to the conductive layer by the conductive adhesive.

10. The method of claim 9, wherein the flexible circuit board further comprises a detecting circuit and a plurality of wires coupling between the detecting circuit and the conductive layer, the detecting circuit is used for determining a contact position of the conductive layer where an external force applied, according to a sensing signal from the conductive layer.

11. The method of claim 9, after the step (j), further comprising:
(k) testing if sensing signals are generated by the conductive layer and transmitted to the flexible circuit board; and
(l) replacing the flexible circuit board when the sensing signals are not transmitted to the flexible circuit board.

12. The method of claim 11, wherein the step (1) comprises:
(11) removing the adhered flexible circuit board from the first glass substrate and the conductive layer;
(12) clearing up the insulating adhesive and the conductive adhesive;
(13) providing another insulating adhesive on the periphery of the first glass substrate;
(14) providing another conductive adhesive on the conductive layer; and
(15) providing and pressing another new FPC, so that the new FPC is adhered and fastened to the first glass substrate and the conductive layer by employing the insulating adhesive and the conductive adhesive, respectively.

13. The method of claim 9, wherein within said step (j), said flexible circuit board comprises a first side non-conductively adhered to the first glass substrate by the insulating adhesive and conductively adhered and fastened to the conductive layer by the conductive adhesive, and said insulating adhesive electrically insulates said flexible circuit board from said metal layer.

14. A touch panel liquid crystal display, comprising:
an array substrate comprising a first glass substrate and a metal layer thereon;
a color filter correspondingly disposed on the array substrate;
a liquid crystal layer disposed between the array substrate and the color filter;
an in-cell touch panel, comprising a second glass substrate and a conductive layer disposed on the color filter, and the color filter sandwiched between the liquid crystal layer and the conductive layer;
a flexible circuit board;
an insulating adhesive, disposed on a periphery of the first glass substrate of the array substrate where the second glass substrate does not overlap, for non-conductively adhering and fastening the flexible circuit board on the array substrate; and
an anisotropic conductive film disposed on a periphery of the conductive layer, for adhering and fastening the flexible circuit board on the conductive layer.

15. The method of manufacturing an in-cell touch liquid crystal display module of claim 10, wherein step (g) is performed so that said insulating adhesive partially overlaps said metal film.

16. The touch panel liquid crystal display of claim 14, wherein the insulating adhesive is a double-sided tape comprising a first adhesion layer, a second adhesion layer, and a base layer between the first adhesion layer and the second adhesion layer.

17. The touch panel liquid crystal display of claim 16, wherein the first adhesion layer and the second adhesion layer is made of Tackified Acrylic.

18. The touch panel liquid crystal display of claim 16, wherein the base layer is made of Polyethylene Terephthalate (PET).

19. The touch panel liquid crystal display of claim 14, wherein a thickness of the insulating adhesive is in a range between 40 micrometers and 550 micrometers.

20. The touch panel liquid crystal display of claim 14, wherein said insulating adhesive partially overlaps said metal layer.
